(19) United States
(12) Patent Application Publication
(10) Pub. No.: US 2007/0034882 A1
(43) Pub. Date: Feb. 15, 2007

(54) SEMICONDUCTOR LIGHT-EMITTING DEVICE

(76) Inventors: Takayoshi Fujii, Yokohama-shi (JP); Junichi Tonotani, Yokohama-shi (JP); Tetsuro Komatsu, Yokohama-shi (JP); Takahiro Sogo, Yokohama-shi (JP); Tomohiro Iguchi, Kawasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/464,366

(22) Filed: Aug. 14, 2006

(30) Foreign Application Priority Data
Aug. 15, 2005 (JP) 2005-235285

(51) Int. Cl. H01L 33/00

(52) U.S. Cl. 257/79

(57) ABSTRACT

An LED chip of the present invention includes a columnar GaP substrate in which a tapered portion whose outer shape is narrowed toward an upper bottom surface side is formed in an outer wall surface thereof, an upper-surface electrode provided in an upper bottom surface of the GaP substrate, a light-emitting layer provided in a lower bottom surface of the GaP substrate, and a lower-surface electrode provided in a surface opposite to the GaP substrate with respect to the light-emitting layer, the lower-surface electrode being arranged in an annular region outside the region opposite to the upper-surface electrode.

### CROSS-REFERENCE TO RELATED APPLICATIONS

This application is based upon and claims the benefit of priority from prior Japanese Patent Application No. 2005-235285, filed Aug. 15, 2005, the entire contents of which are incorporated herein by reference.

### BACKGROUND OF THE INVENTION

1. Field of the Invention

The present invention relates to a semiconductor light-emitting device, particularly to the semiconductor light-emitting device having a structure in which improvement of light extraction efficiency and an increase in total optical output of the light-emitting device can be achieved.

2. Description of the Related Art

FIG. 5 is a side view schematically showing a structure of a conventional junction down-mounted LED chip (semiconductor light-emitting device) 100. The LED chip 100 includes a truncated pyramid-shape GaP substrate 101, a light-emitting layer 102 provided on a lower surface of the GaP substrate 101, a lower-surface electrode 103 provided on the lower surface of the light-emitting layer 102, and an upper-surface electrode 104 provided on an upper surface of the GaP substrate 101. The GaP substrate 101 has a transparent characteristic to a light emission wavelength. The GaP substrate 101 is tapered such that the emitted light is easily extracted outside the chip.

In order to evenly emit the light in the surface, an electrode is formed in the entire lower surface of the lower-surface electrode 103, or the lower-surface electrode 103 is formed by plural thin patterned electrodes 103b to 103d. The upper-surface electrode 104 is formed in a central portion of the upper surface of the GaP substrate 101 in order to perform wire bonding.

In the LED chip 100, as shown in FIG. 5, the light-emitting layer 102 emits the light by passing current between the lower-surface electrode 103 and the upper-surface electrode 104. FIG. 6 shows a light emission intensity distribution of the LED chip 100. In the light beams emitted from the light-emitting layer 102, light beams α1 and α2 which are located within a total internal reflection angle with respect to each surface of the GaP substrate 101 can be extracted outside the chip, while a light beam α3 which is located more than the total internal reflection angle is confined in the chip. The light beam α4 toward the upper-surface electrode 104 is absorbed in the upper-surface electrode 104. Therefore, there is a problem that light extraction efficiency becomes lower.

There is disclosed an LED chip, in which a light-emitting layer is selectively formed in a region except for a portion located immediately below an upper electrode and thereby the emitted light is passed through the portion located immediately below the upper electrode to improve the light extraction efficiency (for example, see Japanese Patent No. 2792781).

There is disclosed an LED chip, in which a reflective film is formed in a surface opposite to a light outgoing surface and thereby the light emitted toward the surface opposite to the light outgoing surface is reflected toward the light outgoing surface to improve the light extraction efficiency (for example, see Japanese Patent No. 3312049).

In the conventional LED chip, there are the following problems. That is, in the LED chip disclosed in Japanese Patent No. 2792781, it is necessary that an active layer be partially formed by selectively irradiating a growth layer with a laser beam. However, from the technical standpoint, it is difficult to form the partial active layer, which results in the problem that the number of production processes is increased to increase cost.

The LED chip disclosed in Japanese Patent No. 3312049 is effective when a distance between the light-emitting layer and the surface in which the reflection layer is formed is separated away from each other. However, in the case where the electrode and the reflection layer are formed near the light-emitting layer, the light is emitted in the substantially same shape as the electrode on the light-emitting layer, and the light propagates toward the electrode while not spread. Therefore, there is the problem that the emitted light is absorbed by the electrode while not reflected from the reflection layer.

### BRIEF SUMMARY OF THE INVENTION

In view of the foregoing, an object of the invention is to provide a semiconductor light-emitting device which can realize high-efficiency light emission by decreasing the emitted light confinement in the chip due to the total internal reflection or by decreasing a ratio of which the emitted light is absorbed in the counter electrode.

In order to achieve the object, a semiconductor light-emitting device of the invention is configured as follows.

A semiconductor light-emitting device according to one aspect of the invention comprises: a columnar substrate in which a tapered portion is formed in an outer wall surface, an outer shape of the tapered portion is narrowed toward an upper bottom surface side; an upper-surface electrode provided in an upper bottom surface of the substrate; a light-emitting layer provided in a lower bottom surface of the substrate; and a lower-surface electrode provided in a surface opposite to the substrate with respect to the light-emitting layer, the lower-surface electrode being arranged in an annular region outside the region opposite to the upper-surface electrode.

A semiconductor light-emitting device according to another aspect of the invention comprises: a columnar substrate in which a tapered portion is formed in an outer wall surface, an outer shape of the tapered portion is narrowed toward an upper bottom surface side; an upper-surface electrode provided in an upper bottom surface of the substrate; a light-emitting layer provided in a lower bottom surface of the substrate; and a lower-surface electrode provided in a surface opposite to the substrate with respect to the light-emitting layer, wherein the light-emitting layer is arranged in an annular region outside the region opposite to the upper-surface electrode.

According to the invention, the high-efficiency light emission can be realized by decreasing the emitted light confinement in the chip due to the total internal reflection or by decreasing a ratio of which the emitted light is absorbed in the counter electrode.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a side view schematically showing an LED chip according to a first embodiment of the invention;

FIG. 2 is a graph showing a light emission intensity distribution of the LED chip;

FIG. 3 is a side view schematically showing an LED chip according to a second embodiment of the invention;

FIG. 4 is a side view schematically showing an LED chip according to a third embodiment of the invention;

FIG. 5 is a side view schematically showing a conventional semiconductor light-emitting device; and

FIG. 6 is a graph showing a light emission intensity distribution of the conventional semiconductor light-emitting device.

### DETAILED DESCRIPTION OF THE INVENTION

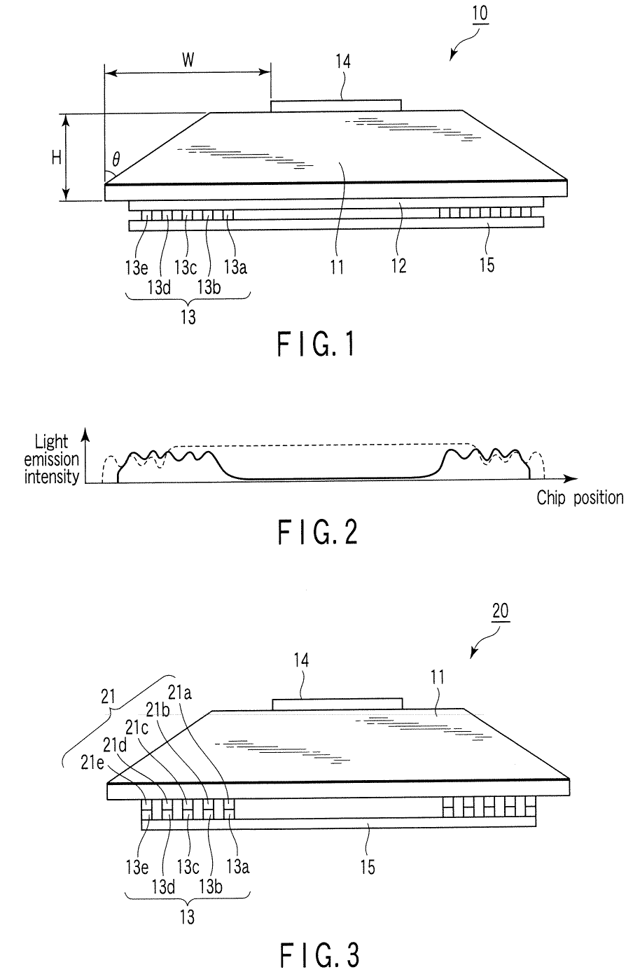

FIG. 1 is a side view schematically showing an LED chip (semiconductor light-emitting device) 10 according to a first embodiment of the invention, and FIG. 2 is a graph showing a light emission intensity distribution of the LED chip 10. The LED chip 10 includes a truncated pyramid-shape GaP substrate 11, a light-emitting layer 12 provided on the lower surface of the GaP substrate 11, a lower-surface electrode 13 provided on the lower surface of the light-emitting layer 12, a lower-surface electrode 13 provided on the lower surface of the light-emitting layer 12, an upper-surface electrode 14 provided on the upper surface of the GaP substrate 11, and a reflective film 15 provided on the lower surface of the lower-surface electrode 13. The GaP substrate 11 has a transparent characteristic to a light emission wavelength. For example, the light-emitting layer 12 is made of InAlGaP.

In the GaP substrate 11, a tapered portion 11a having an angle of θ is provided such that the emitted light is easily extracted outside the chip. It is assumed that a height of the GaP substrate 11 is H.

The upper-surface electrode 14 is formed in the central portion to perform the bonding of wire (not shown).

On the other hand, the lower-surface electrode 13 is arranged so as to satisfy the following three conditions. First, the lower-surface electrode 13 is arranged at a position where the lower-surface electrode 13 does not face the upper-surface electrode 14. This is because the light emission in the light-emitting layer 12 is prevented from being absorbed by the upper-surface electrode 14.

Second, the lower-surface electrode 13 is arranged at a position where the lower-surface electrode 13 is located away from an outer periphery of the GaP substrate 11 by L defined in the formula (1). That is, assuming that W is a distance between the outer periphery of a lower bottom surface of the GaP substrate 11 and the outer periphery of the upper-surface electrode 14, n₁ is a refractive index of the GaP substrate 11, and n₂ is a refractive index of the outside of the GaP substrate 11, the following formula (1) is obtained:
(H/2)tan θ−(H/2)tan(θ+α−90°)<L (1)

where α=sin⁻¹(n₂/n₁)

The formula (1) is one in which a condition that the light emitted from a thin-wire electrode 13e on the outer-most peripheral side is incident within the total internal reflection angle with respect to the tapered surface of the GaP substrate 11 is geometrically determined.

Third, the lower-surface electrode 13 is arranged at a position where the lower-surface electrode 13 is located away from the outer periphery of the GaP substrate 11 by L defined in the following formula (2):
L<(H/2)tan θ+(H/2)tan(−θ+α+90°), and L<W (2)
The formula (2) is one in which a condition that the light emitted from a thin-wire electrode 13a on the inner-most peripheral side is incident within the total internal reflection angle with respect to the tapered surface of the GaP substrate 11 or the lower-surface electrode 13 does not face the upper-surface electrode 14 is geometrically determined.

In the LED chip 10 having the above configuration, the light is emitted near the lower-surface electrode 13 in the light-emitting layer 12 by passing the current between the upper-surface electrode 14 and the lower-surface electrode 13. At this point, because the lower-surface electrode 13 is formed by the thin-wire electrodes 13a to 13e, the light emitted not only from the portions corresponding to the thin-wire electrodes 13a to 13e but also from the portions located between the electrodes. As a result, the light is substantially evenly emitted from the region where the thin-wire electrodes 13a to 13e are provided as a whole. In FIG. 2, a solid line indicates the light emission intensity distribution at this time, and a broken line indicates the light emission intensity distribution of the conventional LED chip shown in FIG. 5 as a comparative example.

The thin-wire electrodes 13a to 13e are arranged at the positions satisfying the above three conditions, the emitted light absorbed by the upper-surface electrode 14 can be suppressed at a minimum while being incident to each surface of the GaP substrate 11 within the total internal reflection angle.

On the other hand, in the light emitted from the light-emitting layer 12, the light leaking onto the lower side of FIG. 1 is reflected from the reflective film 15 to return to the GaP substrate 11, and the light is extracted outside the chip. At this point, because the lower-surface electrode 13 is formed in the thin wire, the light is effectively reflected from the reflective film 15.

Thus, according to the LED chip 10 of the first embodiment, in the light emitted from the light-emitting layer 12, the light confined in the chip or the light absorbed by the upper-surface electrode 11 can be suppressed at a minimum, the light extraction efficiency can be enhanced, and the total optical output can be increased in the light-emitting device. Furthermore, when the electrode structure is determined as described above, it is not necessary to selectively form the active layer with increase in cost, which allows production cost to be reduced.

Other materials may be used as the GaP substrate 11 and light-emitting layer 12 depending on a color and purpose to be emitted. For example, when sapphire is used instead of the GaP substrate 11, GaN may be used as the light-emitting layer 12.

FIG. 3 is a side view schematically showing an LED chip 20 according to a second embodiment of the invention. In FIG. 3, the same functional component as those of FIG. 1 is designated by the same numeral, and the detailed description will be omitted.

In the LED chip 20, light-emitting layer 21a to 21e provided in the lower surface of the GaP substrate 11 is formed in agreement with the positions of the thin-wire electrodes 13a to 13e. In the LED chip 20, the same effect as the first embodiment can also be obtained.

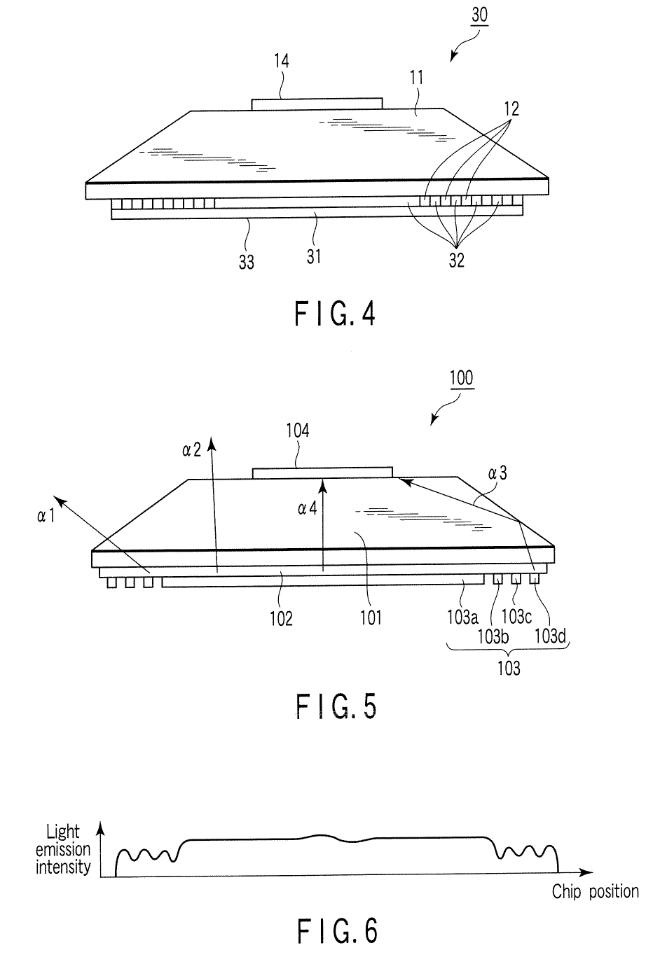

FIG. 4 is a side view schematically showing an LED chip 30 according to a third embodiment of the invention. In FIG. 4, the same functional component as those of FIG. 1 is designated by the same numeral, and the detailed description will be omitted.

The light-emitting layers 21 provided at the positions of the thin-wire electrodes 13a to 13e and an insulating member 32 are arranged In the LED chip 30, and a plate-shape lower-surface electrode 33 is also arranged.

In the LED chip 30 having the configuration of FIG. 4, electric power supplied to the lower-surface electrode 33 is supplied only to the portion where the light-emitting layer 21 is provided, and only the position is emitted. Accordingly, the same effect as the first embodiment can also be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor light-emitting device comprising:
a columnar substrate in which a tapered portion is formed in an outer wall surface, an outer shape of the tapered portion is narrowed toward an upper bottom surface side;
an upper-surface electrode provided in an upper bottom surface of the substrate;
a light-emitting layer provided in a lower bottom surface of the substrate; and
a lower-surface electrode provided in a surface opposite to the substrate with respect to the light-emitting layer, the lower-surface electrode being arranged in an annular region outside the region opposite to the upper-surface electrode.

2. A semiconductor light-emitting device according to claim 1, wherein the lower-surface electrode is arranged larger than (H/2)tan θ−(H/2)tan(θ+α−90°), where α=sin⁻¹(n₂/n₁), and the lower-surface electrode is arranged smaller than both (H/2)tan θ+(H/2)tan(−θ+α+90°) and W, assuming that H is a height of the substrate, θ is an inclined angle of the tapered portion, W is a distance between an outer periphery of a lower bottom surface of the substrate and an outer periphery of the upper-surface electrode, n₁ is a refractive index of the substrate, and n₂ is a refractive index of the outside of the substrate.

3. A semiconductor light-emitting device according to claim 1, wherein the lower-surface electrode is formed in a thin-wire shape, and a reflective film is further provided outside the lower-surface electrode.

4. A semiconductor light-emitting device according to claim 1, wherein the light-emitting layer is formed in the same region as the lower-surface electrode.

5. A semiconductor light-emitting device comprising:
a columnar substrate in which a tapered portion is formed in an outer wall surface, an outer shape of the tapered portion is narrowed toward an upper bottom surface side;
an upper-surface electrode provided in an upper bottom surface of the substrate;
a light-emitting layer provided in a lower bottom surface of the substrate; and
a lower-surface electrode provided in a surface opposite to the substrate with respect to the light-emitting layer,
wherein the light-emitting layer is arranged in an annular region outside the region opposite to the upper-surface electrode.
